(19) United States
(12) Patent Application Publication
(10) Pub. No.: US 2024/0404845 A1
(43) Pub. Date: Dec. 5, 2024

(54) SUBSTRATE PROCESSING APPARATUS AND SUBSTRATE PROCESSING METHOD

(71) Applicant: Tokyo Electron Limited, Tokyo (JP)

(72) Inventor: Hiroshi MARUMOTO, Kumamoto (JP)

(73) Assignee: Tokyo Electron Limited, Tokyo (JP)

(21) Appl. No.: 18/670,732

(22) Filed: May 22, 2024

(30) Foreign Application Priority Data
May 29, 2023 (JP) 2023-087793

(51) Int. Cl. H01L 21/67; G05D 7/06

(52) U.S. Cl. CPC H01L 21/6708; G05D 7/0635

(57) ABSTRACT

A substrate processing apparatus includes a retaining tank, a circulation line, a supply line, a returning line, a flowmeter, a constant-pressure valve, and a controller. The circulation line returns, to the retaining tank, the processing liquid delivered from the retaining tank. The supply line connects the circulation line to a supply unit that supplies the processing liquid to a substrate. The returning line is connected to the supply line to return the processing liquid to the retaining tank. The flowmeter and the constant-pressure valve are provided on the supply line. The controller calculates, during a waiting time interval, an opening degree of the constant-pressure valve in supplying the processing liquid to the substrate based on a measurement value of the flowmeter and an opening degree of the constant-pressure valve, and during a supplying time interval, set an initial opening degree of the constant-pressure valve to the calculated one.

### CROSS-REFERENCE TO RELATED APPLICATION

This application is based upon and claims the benefit of priority of the prior Japanese Patent Application No. 2023-087793, filed on May 29, 2023, the entire contents of which are incorporated herein by reference.

### FIELD

Exemplary embodiment disclosed herein relates to a substrate processing apparatus and a substrate processing method.

### BACKGROUND

Conventionally, there has been known a substrate processing apparatus that is configured to supply processing liquid to a substrate via a supply line from a circulation line in which the processing liquid circulates (see Japanese Laid-open Patent Publication No. 2020-161837, for example).

One aspect of the embodiment is made in view of the aforementioned, and an object of the embodiment is to reduce fluctuation in flow volume at the start of supplying processing liquid to a substrate.

### SUMMARY

A substrate processing apparatus according to one aspect of the present disclosure includes: a retaining tank that retains therein processing liquid; a circulation line that returns, to the retaining tank, the processing liquid delivered from the retaining tank; a supply line that connects the circulation line to a supply unit that supplies the processing liquid to a substrate; a returning line that is connected to the supply line to return the processing liquid from the supply line to the retaining tank; a flowmeter and a constant-pressure valve that are provided on the supply line on an upper flow side than a connecting portion of the returning line and the supply line; and a controller, wherein the controller is configured to: during a waiting time interval in which the processing liquid is caused to flow into the returning line not to supply the processing liquid from the supply unit to the substrate, calculate an opening degree of the constant-pressure valve in supplying the processing liquid to the substrate based on a measurement value of the flowmeter and an opening degree of the constant-pressure valve; and during a supplying time interval in which the processing liquid is caused to flow into the supply unit to supply the processing liquid to the substrate, set an initial opening degree of the constant-pressure valve to the calculated opening degree.

### BRIEF DESCRIPTION OF DRAWINGS

FIG. 1 is a diagram illustrating a schematic configuration of a substrate processing system according to an embodiment;

FIG. 2 is a schematic diagram illustrating a configuration of a process unit according to the embodiment;

FIG. 3 is a diagram illustrating a schematic configuration of a processing liquid supply source according to the embodiment;

FIG. 4 is a diagram illustrating flow of IPA during a supplying time interval according to the embodiment;

FIG. 5 is a diagram illustrating flow of IPA during a waiting time interval according to the embodiment;

FIG. 6 is a flowchart illustrating processing in switching from the waiting time interval into the supplying time interval according to the embodiment; and

FIG. 7 is a diagram illustrating a schematic configuration of a processing liquid supply source according to a modification of the embodiment.

### DESCRIPTION OF EMBODIMENT

Hereinafter, an exemplary embodiment (hereinafter, may be referred to as “embodiment”) of a substrate processing apparatus and a substrate processing method will be described in detail with reference to the accompanying drawings. In addition, the illustrative embodiment disclosed below is not intended to limit the disclosed technology.

Conventionally, there has been known a substrate processing apparatus that is configured to supply processing liquid to a substrate via a supply line from a circulation line in which the processing liquid circulates. A configuration for returning processing liquid to a circulation line without supplying the processing liquid to a substrate by using a returning line connected to a supply line may be employed for the above-mentioned substrate processing apparatus.

However, in the configuration for returning processing liquid to a circulation line by using a returning line connected to a supply line, in a case where switching a flowing destination of processing liquid from a returning line into a supply line so as to start to supply processing liquid to a substrate, there presents possibility that fluctuation in flow volume of the processing liquid occurs due to change in the viscosity, which is caused by disturbance. As the disturbance, there are supposed, for example, a residence time interval of processing liquid remaining in lines during a time period in which processing liquid is not supplied to a substrate, the environmental temperature, and the like.

Thus, there has been desired a technology that is capable of reducing fluctuation in flow volume when starting supply of processing liquid to a substrate.

### Outline of Substrate Processing System

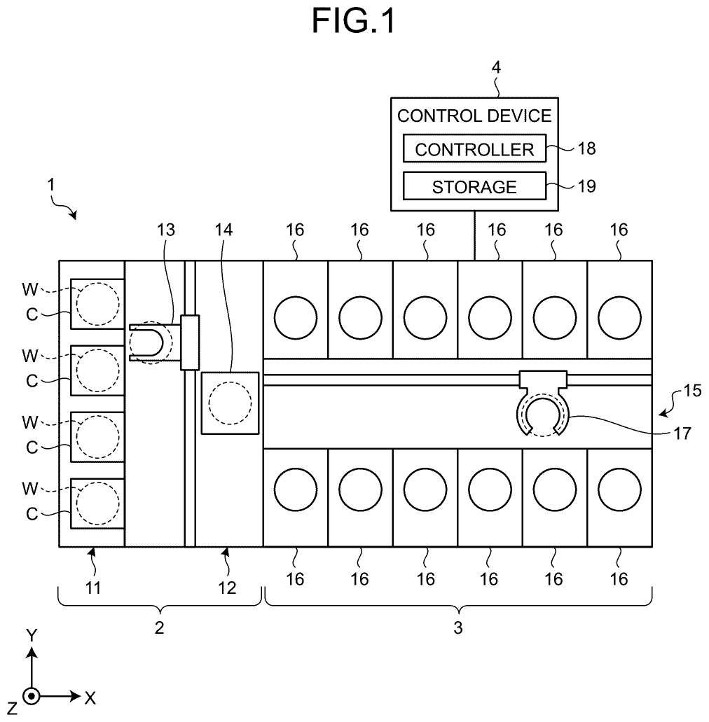

A schematic configuration of a substrate processing system 1 (one example of substrate processing apparatus) according to the embodiment will be explained with reference to FIG. 1. FIG. 1 is a diagram illustrating a schematic configuration of the substrate processing system 1 according to an embodiment. Hereinafter, in order to clarify positional relation, an X-axis, a Y-axis, and a Z-axis are defined, which are perpendicular to one another, and further a positive Z-axis direction is defined as an upward direction in the vertical direction.

As illustrated in FIG. 1, the substrate processing system 1 includes a carry-in/out station 2 and a processing station 3. The carry-in/out station 2 and the processing station 3 are provided adjacent to each other.

The carry-in/out station 2 includes a carrier placing section 11 and a transfer section 12. In the carrier placing section 11, a plurality of carriers C is placed to horizontally accommodate a plurality of substrates, namely, semiconductor wafers W (hereinafter, wafer W) in the present embodiment.

The transfer section 12 is provided adjacent to the carrier placing section 11, and includes therein a substrate transfer device 13 and a delivery unit 14. The substrate transfer device 13 includes a wafer holding mechanism configured to hold the wafer W. The substrate transfer device 13 is movable horizontally and vertically and is pivotable around a vertical axis, and transfers the wafer W between the corresponding carrier C and the delivery unit 14 by using the wafer holding mechanism.

The processing station 3 is provided adjacent to the transfer section 12. The processing station 3 includes a transfer section 15 and a plurality of processing units 16. The plurality of processing units 16 is provided side by side at both sides of the transfer section 15.

The transfer section 15 includes therein a substrate transfer device 17. The substrate transfer device 17 includes a wafer holding mechanism configured to hold the wafer W. The substrate transfer device 17 is movable horizontally and vertically and is pivotable around the vertical axis, and transfers the wafer W between the delivery unit 14 and the corresponding processing unit 16 by using the wafer holding mechanism.

Each of the processing units 16 performs substrate processing on the wafer W transferred by the substrate transfer device 17. The processing unit 16 holds the transferred wafer so as to execute substrate processing on the held wafer. The processing unit 16 supplies processing liquid to the held wafer so as to execute thereon substrate processing.

The processing liquid is etchant, for example. The etchant is not particularly limited, and hydrofluoric acid (HF) aqueous solution, organic chemical liquid, or the like may be employed therefor, for example. For the organic chemical liquid, for example, tetramethylammonium hydroxide, or the like may be employed. As the organic chemical liquid, aqueous solution including amines and/or alkanolamines may be used. Moreover, the processing liquid may be a replacement solution such as isopropyl alcohol (IPA).

The substrate processing system 1 further includes a control device 4. The control device 4 is a computer, for example, so as to include a controller 18 and a storage 19. The storage 19 stores therein a program for controlling various types of processes that are performed in the substrate processing system 1. The controller 18 reads out and executes the program stored in the storage 19 to control operations of the substrate processing system 1.

The program may be recorded in a computer-readable recording medium and thus may be installed into the storage 19 of the control device 4 from the recording medium. A computer-readable recording medium includes, for example, a hard disk (HD), a flexible disk (FD), a compact disc (CD), a magneto-optical disk (MO), and a memory card among other things.

In the substrate processing system 1 configured as described above, the substrate transfer device 13 of the carry-in/out station 2 first takes out the wafer W from one of the carriers C placed in the carrier placing section 11, and places the taken wafer W on the delivery unit 14. The wafer W placed on the delivery unit 14 is taken out from the delivery unit 14 by the substrate transfer device 17 of the processing station 3, and is carried into one of the processing units 16.

The wafer W carried into the processing unit 16 is processed by the processing unit 16, and then is carried out from the processing unit 16 and placed on the delivery unit 14 by using the substrate transfer device 17. Next, the processed wafer W placed on the delivery unit 14 is returned to the corresponding carrier C in the carrier placing section 11 by using the substrate transfer device 13.

### Outline of Processing Unit

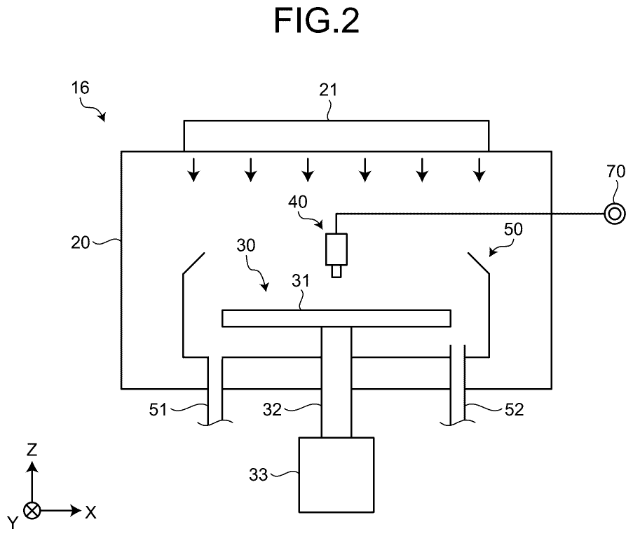

Next, a configuration of the processing unit 16 according to the embodiment will be explained with reference to FIG. 2. FIG. 2 is a schematic diagram illustrating a configuration of the processing unit 16 according to the embodiment. The processing unit 16 includes a chamber 20, a substrate holding mechanism 30, a processing-liquid supplying unit 40, and a recovery cup 50.

The chamber 20 accommodates therein the substrate holding mechanism 30, the processing-liquid supplying unit 40, and the recovery cup 50. A Fan Filter Unit (FFU) 21 is provided in a ceiling portion of the chamber 20. The FFU 21 forms down flow in the chamber 20.

The substrate holding mechanism 30 includes a holding unit 31, a supporting unit 32, and a drive unit 33. The holding unit 31 horizontally holds the wafer W. The supporting unit 32 is a member extending along the vertical direction, a bottom end thereof is supported by the drive unit 33 to be rotatable, and a leading end thereof horizontally supports the holding unit 31. The drive unit 33 rotates the supporting unit 32 around a vertical axis.

The substrate holding mechanism 30 causes the drive unit 33 to rotate the supporting unit 32, so as to rotate the holding unit 31 that is supported by the supporting unit 32. Thus, the wafer W held by the holding unit 31 rotates.

The processing-liquid supplying unit 40 (one example of supply unit) supplies processing liquid to the wafer W (one example of substrate). The processing-liquid supplying unit 40 is connected to a processing liquid supply source 70. The processing-liquid supplying unit 40 includes a plurality of nozzles. For example, the plurality of nozzles is provided so as to correspond to respective processing liquids. Each of the nozzles discharges, toward the wafer W, processing liquid that is supplied from the corresponding processing liquid supply source 70.

The recovery cup 50 is formed so as to surround the holding unit 31, so that the recovery cup 50 collects processing liquid that is splashed from the wafer W by rotation of the holding unit 31. A drain port 51 is formed in a bottom portion of the recovery cup 50. Processing liquid collected by the recovery cup 50 is discharged toward the outside of the processing unit 16 from the above-mentioned drain port 51. An exhaust port 52 is formed in a bottom portion of the recovery cup 50, which discharges gas supplied from the FFU 21 toward the outside of the processing unit 16.

### Outline of Processing Liquid Supply Source

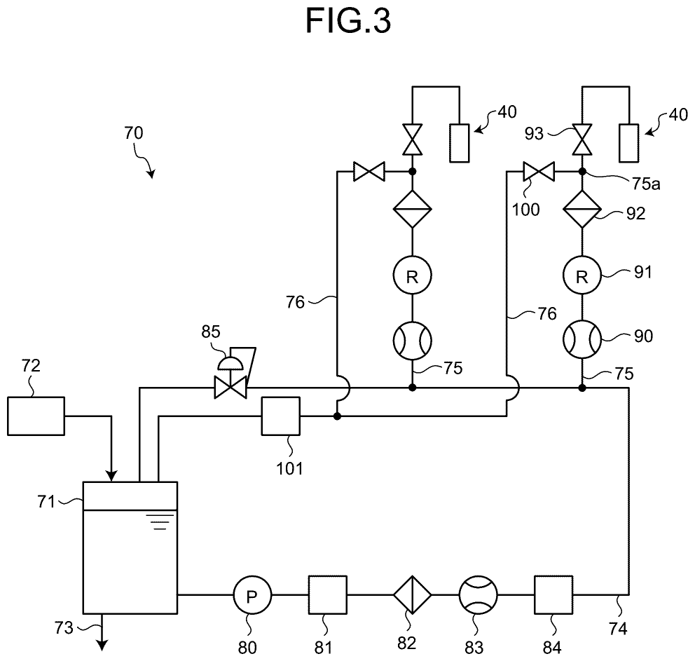

Next, the processing liquid supply source 70 will be explained with reference to FIG. 3. FIG. 3 is a diagram illustrating a schematic configuration of the processing liquid supply source 70 according to the embodiment. Herein, the processing liquid supply source 70 that supplies IPA will be explained as one example. A configuration of the processing liquid supply source 70 illustrated in FIG. 3 may be applied to a configuration of a processing liquid supply source that supplies, not limited to IPA, another processing liquid. In FIG. 3, one example is indicated in which the processing liquid supply source 70 supplies IPA to the two processing-liquid supplying units 40; however, not limited thereto. The processing liquid supply source 70 supplies IPA to the plurality of processing-liquid supplying units 40. The processing liquid supply source 70 may supply IPA to the single processing-liquid supplying unit 40.

The processing liquid supply source 70 includes a tank 71, a processing-liquid replenishing unit 72, a waste liquid line 73, a circulation line 74, supply lines 75, and returning lines 76.

The tank 71 (one example of retaining tank) retains therein IPA (one example of processing liquid). The temperature of IPA is 20° C. to 80° C., for example. Processing liquid to be retained in the tank 71 is not limited to IPA, and may be another processing liquid such as HF solution and organic chemical liquid. In a case where a processing liquid to be retained in the tank 71 is organic chemical liquid, the temperature of the organic chemical liquid is 20° C. to 80° C., for example. In a case where a processing liquid to be retained in the tank 71 is HF solution, the temperature of the HF solution is 20° C. to 50° C., and the concentration of HF in the HF solution is 1.12 wt % to 50 wt %.

The processing-liquid replenishing unit 72 supplies a fresh IPA to the tank 71. For example, the processing-liquid replenishing unit 72 supplies a fresh IPA to the tank 71 in a case where IPA in the tank 71 is exchanged or IPA in the tank 71 is less than a predetermined amount.

In a case where exchanging IPA in the tank 71, the waste liquid line 73 discharges IPA from the tank 71 to the outside thereof so as to discard IPA. In a case where exchanging IPA in the tank 71, circulation of IPA may be performed while supplying a fresh IPA; and IPA remaining in the circulation line 74, the supply line 75, and the returning line 76 may be discarded. In other words, IPA including the IPA remaining in the circulation line 74, the supply line 75, and the returning line 76 may be exchanged.

Both ends of the circulation line 74 are connected to the tank 71 so as to return IPA delivered from the tank 71 into the tank 71. The circulation line 74 is configured such that IPA flows outside of the tank 71, and further returns to the tank 71 again. The circulation line 74 is configured to be capable of supplying IPA to the plurality of processing units 16.

The circulation line 74 is provided with a pump 80, a heater 81, a filter 82, a flowmeter 83, a temperature sensor 84, and a back pressure valve 85. Specifically, in a flowing direction of IPA starting from the tank 71; the pump 80, the heater 81, the filter 82, the flowmeter 83, the temperature sensor 84, and the back pressure valve 85 are provided in this order on the circulation line 74 from an upper flow side.

The pump 80 pressure-feeds IPA in the circulation line 74. The pressure-fed IPA circulates through the circulation line 74 to return to the tank 71.

The heater 81 is provided on the circulation line 74 so as to adjust the temperature of IPA. Specifically, the heater 81 heats IPA. The heater 81 controls a heating amount of IPA on the basis of a signal transmitted from the control device 4, so as to adjust the temperature of IPA. For example, a heating amount of IPA by the heater 81 is adjusted on the basis of the temperature of IPA, which is detected by the temperature sensor 84.

For example, the control device 4 controls the heater 81 so as to adjust the temperature of IPA to a predetermined temperature. The predetermined temperature is a temperature at which the temperature of IPA, which is discharged during a supplying time interval from a nozzle of the processing-liquid supplying unit 40 to the wafer W, is a preset processing temperature. The predetermined temperature is a temperature that is set on the basis of a heat capacity of a filter 92 that is provided on the supply line 75 or the like.

The filter 82 is configured to remove an extraneous substance that is a contaminant such as a particle included in IPA flowing through the circulation line 74. The flowmeter 83 measures a flow volume of IPA flowing through the circulation line 74. The temperature sensor 84 detects a temperature of IPA flowing through the circulation line 74. The temperature sensor 84 is arranged on the circulation line 74 on an upper flow side thereof than a portion where the supply line 75 is connected.

The back pressure valve 85 increases an opening degree thereof in a case where a pressure of IPA on an upper flow side of the back pressure valve 85 is larger than a predetermined pressure. The back pressure valve 85 reduces an opening degree thereof in a case where a pressure of IPA on an upper flow side of the back pressure valve 85 is smaller than the predetermined pressure. The back pressure valve 85 has a function for maintaining a pressure of processing liquid on the upper flow side at the predetermined pressure. The predetermined pressure is a preset pressure. An opening degree of the back pressure valve 85 is controlled by the control device 4 (see FIG. 1).

The back pressure valve 85 is capable of adjusting a flow volume of IPA in the circulation line 74 by controlling an opening degree thereof. In other words, the back pressure valve 85 is provided on the circulation line 74 so as to adjust a flow volume of IPA returning to the tank 71 via the circulation line 74. Note that a flow volume of IPA in the circulation line 74 may be adjusted by controlling a discharging pressure of the pump 80. A flow volume of IPA in the circulation line 74 is controlled on the basis of a flow volume of IPA that is detected by the flowmeter 83.

The supply lines 75 are connected to the circulation line 74. Each of the supply line 75 is located on a downstream side from the temperature sensor 84 to be connected to the circulation line 74 on an upper flow side than the back pressure valve 85. The plurality of supply lines 75 is provided corresponding to the plurality of processing-liquid supplying units 40. Each of the supply lines 75 is provided so as to branch from the circulation line 74 to be capable of supplying IPA to the processing-liquid supplying unit 40. Each of the supply lines 75 connects the circulation line 74 and the corresponding processing-liquid supplying unit 40 that supplies IPA to the wafer W.

Each of the supply lines 75 is provided with a flowmeter 90, a constant-pressure valve 91, the filter 92, and an open/close valve 93. Specifically, the supply line 75 is provided with the flowmeter 90, the constant-pressure valve 91, the filter 92, and the open/close valve 93 in this order from a side of the circulation line 74. In other words, the supply line 75 is provided with the flowmeter 90, the constant-pressure valve 91, the filter 92, and the open/close valve 93 in this order from an upper flow side of a flowing direction of IPA that flows from the circulation line 74 to the processing-liquid supplying unit 40.

The flowmeter 90 and the constant-pressure valve 91 are provided on the supply line 75 on an upper flow side than a connecting portion 75a of the returning line 76 and the supply line 75. The flowmeter 90 measures a flow volume of IPA that flows through the supply line 75. The constant-pressure valve 91 changes an opening degree thereof so as to adjust the pressure of IPA on a downstream side from the constant-pressure valve 91. For example, the constant-pressure valve 91 adjusts the pressure of IPA such that a discharge amount of IPA discharged from a nozzle of the processing-liquid supplying unit 40 is a predetermined discharge amount. In other words, the constant-pressure valve 91 changes an opening degree thereof so as to adjust a flow volume of IPA that is discharged from a nozzle of the processing-liquid supplying unit 40. The predetermined discharge amount is a preset amount, and is set in accordance with a processing condition of the wafer W. An opening degree of the constant-pressure valve 91 is controlled by the control device 4.

The filter 92 is provided on the supply line 75 on an upper flow side than the connecting portion 75a of the returning line 76 and the supply line 75. The filter 92 is provided on the supply line 75 on a downstream side from the constant-pressure valve 91. The filter 92 is configured to remove an extraneous substance that is a contaminant such as a particle included in IPA flowing through the supply line 75.

The open/close valve 93 switches between presence/absence of supply of IPA to the processing-liquid supplying unit 40. In a case where the open/close valve 93 opens, IPA is supplied to the processing-liquid supplying unit 40. In other words, the open/close valve 93 is opened, thereby leading to discharging IPA from a nozzle of the processing-liquid supplying unit 40. In a case where the open/close valve 93 closes, IPA is not supplied to the processing-liquid supplying unit 40. In other words, the open/close valve 93 is closed, thereby leading to stop of discharging IPA from a nozzle of the processing-liquid supplying unit 40. The open/close valve 93 is opened/closed on the basis of a signal transmitted from the control device 4. In other words, the open/close valve 93 is controlled by the control device 4.

The returning line 76 is connected to the supply line 75 so as to return IPA from the supply line 75 to the tank 71. The returning line 76 is connected to the supply line 75 in the connecting portion 75a that is arranged between the filter 92 and the open/close valve 93. The plurality of returning lines 76 is respectively provided in accordance with the plurality of processing-liquid supplying units 40. The returning line 76 is provided with an open/close valve 100.

The open/close valve 100 switches between presence/absence of flow of IPA in the returning line 76. In a case where the open/close valve 100 opens, IPA flows from the supply line 75 to the returning line 76. IPA flowing through the returning line 76 is returned to the tank 71. In a case where the open/close valve 100 closes, IPA does not flow into the returning line 76. The open/close valve 100 is opened/closed on the basis of a signal transmitted from the control device 4. In other words, the open/close valve 100 is controlled by the control device 4.

Each of the open/close valves 93 and 100 (one example of switching unit) switches flow of IPA into the returning line 76 or the supply line 75 closer to the processing-liquid supplying unit 40 than the connecting portion 75a.

The plurality of returning lines 76 is joined on a downstream side from the open/close valve 100 in a flowing direction of IPA that is flowing through the returning line 76, and further is connected to the tank 71. A temperature sensor 101 is provided on the returning line 76 on a downstream side from a portion in which the plurality of returning line 76 is joined. The temperature sensor 101 detects a temperature of IPA that returns from the returning line 76 to the tank 71. Note that the returning line 76 may be connected to the circulation line 74 on a downstream side from the back pressure valve 85.

### Flow of IPA During Supplying Time Interval

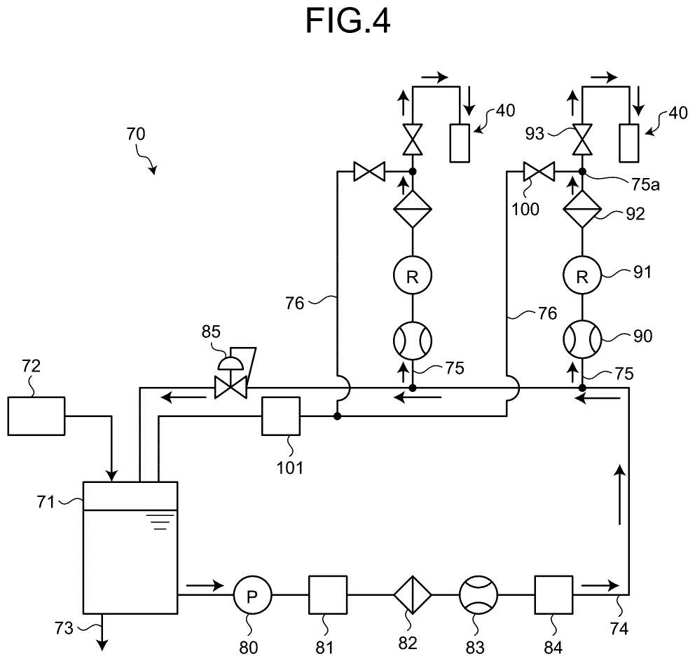

Next, flow of IPA during a supplying time interval will be explained with reference to FIG. 4. FIG. 4 is a diagram illustrating flow of IPA during a supplying time interval according to the embodiment.

During a supplying time interval for supplying IPA from the processing-liquid supplying unit 40 to the wafer W, the control device 4 controls the open/close valves 93 and 100 such that IPA flows into the processing-liquid supplying units 40. Specifically, during the supplying time interval, the control device 4 closes the open/close valve 100 provided on the returning line 76, and further opens the open/close valve 93 provided on the supply line 75. Thus, IPA does not flow into the returning line 76 to be discharged from a nozzle of the processing-liquid supplying unit 40.

### Flow of IPA During Waiting Time Interval

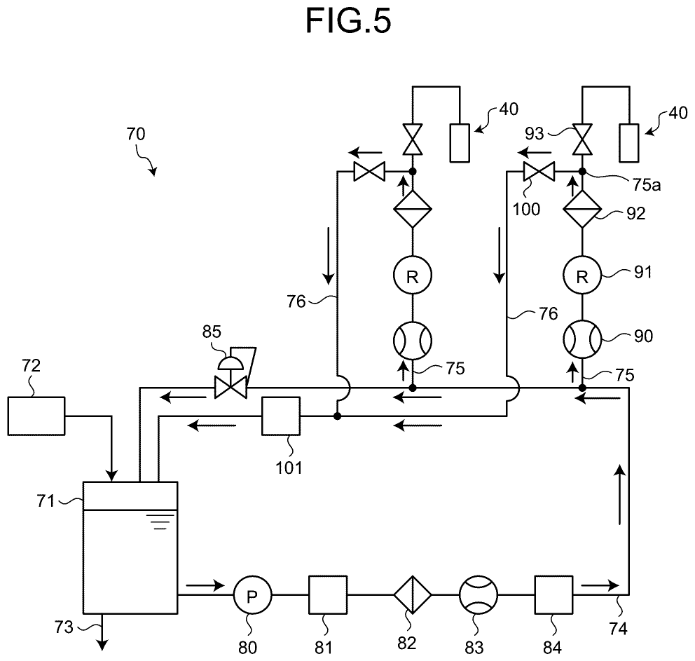

Next, flow of IPA during a waiting time interval will be explained with reference to FIG. 5. FIG. 5 is a diagram illustrating flow of IPA during a waiting time interval according to the embodiment.

During a waiting time interval for not supplying IPA from the processing-liquid supplying unit 40 to the wafer w, the control device 4 controls the open/close valves 93 and 100 such that IPA flows into the returning line 76. Specifically, during the waiting time interval, the control device 4 closes the open/close valve 93 provided on the supply line 75, and further opens the open/close valve 100 provided on the returning line 76. Thus, IPA is not discharged from a nozzle of the processing-liquid supplying unit 40, and further is returned to the tank 71 via the returning line 76.

In the plurality of processing units 16, open/close of the open/close valves 93 and 100 is individually controlled in accordance with a processing situation of the corresponding wafer W in each of the processing units 16.

A flow volume of IPA flowing into the returning line 76 during a waiting time interval is equal to a flow volume of IPA flowing into the supply line 75 during a supplying time interval. Thus, open/close of each of the open/close valves 93 and 100 is switched, so that it is possible to supply a predetermined discharge amount of IPA to the corresponding wafer W.

Control in Switching from Waiting Time Interval to Supplying Time Interval

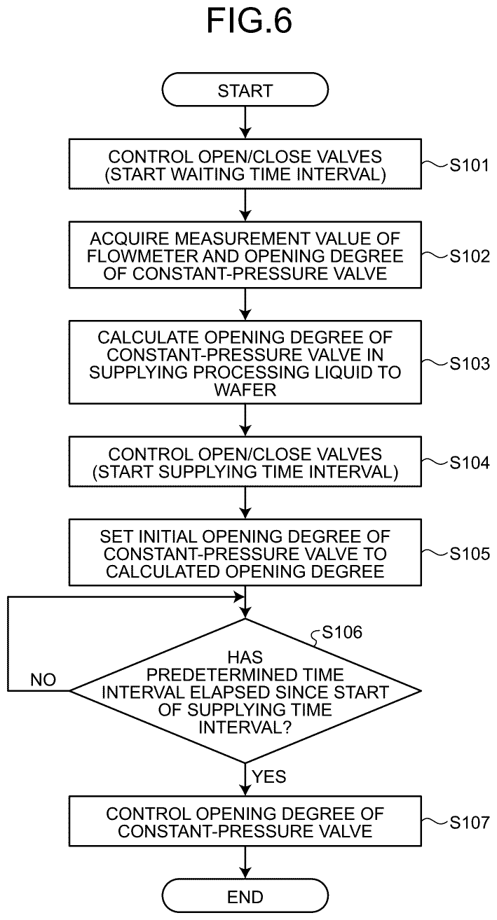

Next, a process in switching from a waiting time interval to a supplying time interval will be explained with reference to FIG. 6. FIG. 6 is a flowchart illustrating processing in switching from the waiting time interval into the supplying time interval according to the embodiment.

The control device 4 controls the open/close valves 93 and 100 such that IPA flows into the returning line 76 (Step S101). Thus, the control device 4 starts a waiting time interval for flowing IPA into the returning line 76 so as not to supply processing liquid from the processing-liquid supplying unit 40 to the wafer W.

During the waiting time interval, the control device 4 executes feed-back control on an opening degree of the constant-pressure valve 91 such that a measurement value of the flowmeter 90 is maintained at a predetermined value.

The control device 4 acquires a measurement value of the flowmeter 90 and an opening degree of the constant-pressure valve 91 (Step S102). The opening degree of the constant-pressure valve 91 is acquired from an opening-degree detecting sensor (not illustrated) that is provided in the constant-pressure valve 91, for example. For the opening-degree detecting sensor, a rotary encoder may be employed, for example.

The control device 4 calculates an opening degree of the constant-pressure valve 91 in supplying IPA to the wafer W on the basis of a measurement value of the flowmeter 90 and an opening degree of the constant-pressure valve 91 (Step S103). Specifically, the control device 4 calculates an opening degree of the constant-pressure valve 91 in supplying IPA to the wafer W with the use of a measurement value of the flowmeter 90 and an opening degree of the constant-pressure valve 91 during a waiting time interval, and a predetermined calculating formula.

Herein, the predetermined calculating formula is a calculating formula for estimating an opening degree of the constant-pressure valve 91 when IPA is supplied to the wafer W. Specifically, the predetermined calculating formula is a calculating formula for estimating an opening degree of the constant-pressure valve 91 when IPA is supplied to the wafer W, based on a measurement value of the flowmeter 90 and an opening degree of the constant-pressure valve 91 during a waiting time interval. The opening degree of the constant-pressure valve 91 when IPA is supplied to the wafer W is a convergence value of an opening degree of the constant-pressure valve 91 in a case where feed-back control is supposed to be executed on the constant-pressure valve 91 during a supplying time interval for supplying IPA to the wafer W. As a result of intensive studies, an inventor of the present application found that a measurement value of the flowmeter 90 and an opening degree of the constant-pressure valve 91 during a waiting time interval, and an opening degree of the constant-pressure valve 91 when IPA was supplied to the wafer W correlated with each other. Thus, the substrate processing system 1 according to the embodiment is configured to calculate, before switching from a waiting time interval to a supplying time interval, an opening degree of the constant-pressure valve 91 when IPA is supplied to the wafer W, on the basis of a measurement value of the flowmeter 90 and an opening degree of the constant-pressure valve 91 during a waiting time interval.

A calculating formula, which indicates correlation between a measurement value of the flowmeter 90 and an opening degree of the constant-pressure valve 91 during a waiting time interval, and an opening degree of the constant-pressure valve 91 when IPA is supplied to the wafer W, is indicated by the following formula (1), for example.

$$( opening degree of \text{constant-pressure} valve 91 when IPA is supplied to wafer W ) = α + β \times ( meaurement value of flowmeter 90 ) + γ \times ( opening degree of \text{constant-pressure} valve 91 ) \qquad ( 1 )$$

Note that α, β, and γ are coefficients obtained by analysis, experiments, or the like.

For example, the control device 4 substitutes a measurement value of the flowmeter 90 and an opening degree of the constant-pressure valve 91, which are acquired during a waiting time interval, into a calculating formula of the formula (1), so as to be capable of calculating an opening degree of the constant-pressure valve 91 when IPA is supplied to the wafer W.

The control device 4 controls the open/close valves 93 and 100 such that IPA flows into the processing-liquid supplying unit 40 (Step S104). Thus, the control device 4 causes IPA to flow into the processing-liquid supplying unit 40 so as to start a supplying time interval for supplying processing liquid to the wafer W. In other words, the control device 4 switches from a waiting time interval into a supplying time interval.

The control device 4 sets an initial opening degree of the constant-pressure valve 91 to an opening degree that is calculated in Step S103 (Step S105). Thus, it is possible to reduce a change in a viscosity of IPA due to disturbance when a flowing destination of IPA is changed from the returning line 76 into the processing-liquid supplying unit 40 to start to supply IPA to the wafer W. For example, it is possible to reduce effects due to a residence time interval of processing liquid remaining in the returning line 76 and the supply line 75 during a time period in which IPA is not supplied to a wafer, disturbance such as environmental temperature, among other things. Thus, it is possible to reduce fluctuation in flow volume in starting to supply IPA to the wafer W.

The control device 4 determines whether or not a predetermined time interval has elapsed since start of the supplying time interval (Step S106). The predetermined time interval is a time interval for removing processing liquid remaining in the returning line 76 and the supply line 75 during a time period in which IPA is not supplied to a wafer, for example. The predetermined time interval is equal to or more than one second to less than five seconds, for example.

Until the predetermined time interval has elapsed since the supplying time interval is started (Step S106: No), the control device 4 maintains an opening degree of the constant-pressure valve 91 at an initial opening degree that is set in Step S105.

In a case where the predetermined time interval has elapsed (Step S106: Yes) since start of a supplying time interval, the control device 4 executes feed-back control on an opening degree of the constant-pressure valve 91 so as to maintain a measurement value of the flowmeter 90 at a predetermined value (Step S107). The above-mentioned feed-back control executed on the constant-pressure valve 91 continues until the supplying time interval ends.

### Effects

As described above, a substrate processing apparatus (for one example, substrate processing system 1) according to the embodiment includes a retaining tank (for one example, tank 71), a circulation line (for one example, circulation line 74), a supply line (for one example, supply line 75), a returning line (for one example, returning line 76), a flowmeter (for one example, flowmeter 90), a constant-pressure valve (for one example, constant-pressure valve 91), and a controller (for one example, the control device 4). The retaining tank retains therein processing liquid (for one example, IPA). The circulation line returns, to the retaining tank, the processing liquid delivered from the retaining tank. The supply line connects the circulation line to a supply unit (for one example, processing-liquid supplying unit 40) that supplies the processing liquid to a substrate (for one example, wafer W). The returning line is connected to the supply line to return the processing liquid from the supply line to the retaining tank. The flowmeter and the constant-pressure valve are provided on the supply line on an upper flow side than a connecting portion of the returning line and the supply line. During a waiting time interval in which the processing liquid is caused to flow into the returning line not to supply the processing liquid from the supply unit to the substrate, the controller calculates an opening degree of the constant-pressure valve in supplying the processing liquid to the substrate based on a measurement value of the flowmeter and an opening degree of the constant-pressure valve. During a supplying time interval in which the processing liquid is caused to flow into the supply unit to supply the processing liquid to the substrate, the controller sets an initial opening degree of the constant-pressure valve to the calculated opening degree. Thus, it is possible to reduce fluctuation in flow volume when starting to supply processing liquid to a substrate.

The controller maintains an opening degree of the constant-pressure valve at the set initial opening degree during a time interval until a predetermined time interval is elapsed from start of the supplying time interval. The controller controls an opening degree of the constant-pressure valve such that a measurement value of the flowmeter is maintained at a predetermined value during a time interval until end of the supplying time interval from a time point when the predetermined time interval is elapsed. Thus, it is possible to more reliably reduce fluctuation in flow volume in starting to supply processing liquid to a substrate.

The processing liquid includes an IPA, an HF solution, or an organic chemical liquid. Thus, it is possible to reduce fluctuation in flow volume in starting to supply an IPA, an HF solution, or an organic chemical liquid to a substrate.

### Modification

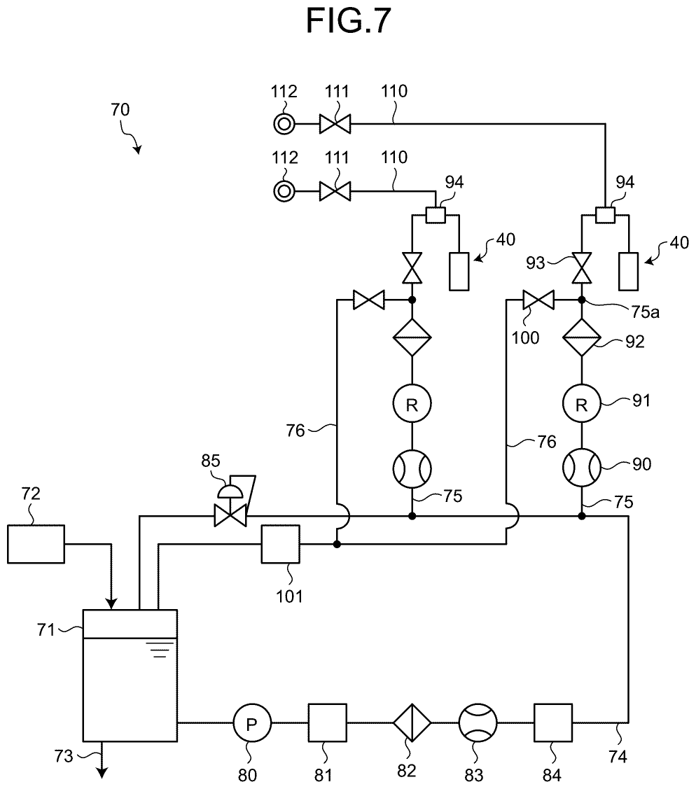

As illustrated in FIG. 7, the processing liquid supply source 70 of the substrate processing system 1 may be configured as a processing liquid supply system that supplies mixed solution of two kinds of processing liquids. FIG. 7 is a diagram illustrating a schematic configuration of the processing liquid supply source 70 according to a modification of the embodiment. Herein, a configuration example of the processing liquid supply source 70 as a processing liquid supply system will be explained, which supplies Sulfuric acid Hydrogen Peroxide Mixture (SPM) solution of mixed solution obtained by mixing a sulfuric acid and a hydrogen peroxide.

The processing liquid supply source 70 illustrated in FIG. 7 includes, as a supply system of sulfuric acid, the tank 71, the processing-liquid replenishing unit 72, the waste liquid line 73, the circulation line 74, the supply line 75, and the returning line 76. In other words, in the processing liquid supply source 70 illustrated in FIG. 7, IPA that is processing liquid in the above embodiment is replaced with sulfuric acid. In a case where processing liquid is sulfuric acid, the supply line 75 is configured such that the supply line 75 branches from the circulation line 74 so as to cause sulfuric acid to flow into a mixing unit 94 to be mentioned later of the supply line 75.

The processing liquid supply source 70 includes, as a supply system of hydrogen peroxide, a hydrogen peroxide supply line 110, an open/close valve 111, and a hydrogen peroxide supply source 112. One end of the hydrogen peroxide supply line 110 is connected to the hydrogen peroxide supply source 112 via the open/close valve 111, and further the other end of the hydrogen peroxide supply line 110 is connected to the mixing unit 94 of the supply line 75. The processing liquid supply source 70 supplies hydrogen peroxide, which is supplied from the hydrogen peroxide supply source 112, to the mixing unit 94 of the supply line 75 via the hydrogen peroxide supply line 110.

The processing liquid supply source 70 includes the mixing unit 94. The mixing unit 94 is provided on the supply line 75 closer to the processing-liquid supplying unit 40 than the connecting portion 75a connected to the returning line 76. The mixing unit 94 mixes sulfuric acid (one example of processing liquid) supplied from the supply line 75 and hydrogen peroxide (one example of second processing liquid) supplied from the hydrogen peroxide supply line 110 so as to generate SPM liquid that is mixed solution, and further supplies the generated SPM liquid to the processing-liquid supplying unit 40. The processing-liquid supplying unit 40 supplies, to the wafer W, SPM liquid supplied from the mixing unit 94. According to the modification, it is possible to reduce fluctuation in flow volume in starting to supply SPM liquid to the wafer W.

In the above embodiment, an opening degree of the constant-pressure valve 91 is maintained at a set initial opening degree during a time interval until a predetermined time interval is elapsed from start of a supplying time interval; however, the disclosed technology is not limited thereto. For example, the control device 4 may maintain an opening degree of the constant-pressure valve 91 at the set initial opening degree during whole of the supplying time interval.

According to the present disclosure, it is possible to reduce fluctuation in flow volume in starting to supply processing liquid to a substrate.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A substrate processing apparatus comprising:
a retaining tank that retains therein processing liquid;
a circulation line that returns, to the retaining tank, the processing liquid delivered from the retaining tank;
a supply line that connects the circulation line to a supply unit that supplies the processing liquid to a substrate;
a returning line that is connected to the supply line to return the processing liquid from the supply line to the retaining tank;
a flowmeter and a constant-pressure valve that are provided on the supply line on an upper flow side than a connecting portion of the returning line and the supply line; and
a controller, wherein
the controller is configured to:
during a waiting time interval in which the processing liquid is caused to flow into the returning line not to supply the processing liquid from the supply unit to the substrate, calculate an opening degree of the constant-pressure valve in supplying the processing liquid to the substrate based on a measurement value of the flowmeter and an opening degree of the constant-pressure valve; and
during a supplying time interval in which the processing liquid is caused to flow into the supply unit to supply the processing liquid to the substrate, set an initial opening degree of the constant-pressure valve to the calculated opening degree.

2. The substrate processing apparatus according to claim 1, wherein
the controller is further configured to:
control an opening degree of the constant-pressure valve such that an opening degree of the constant-pressure valve is maintained at the set initial opening degree during a time interval until a predetermined time interval is elapsed from start of the supplying time interval, and a measurement value of the flowmeter is maintained at a predetermined value during a time interval until end of the supplying time interval from a time point when the predetermined time interval is elapsed.

3. The substrate processing apparatus according to claim 1, wherein
the controller is further configured to:
maintain an opening degree of the constant-pressure valve at the set initial opening degree during whole of the supplying time interval.

4. The substrate processing apparatus according to claim 1, wherein
the processing liquid includes an IPA, an HF solution, or an organic chemical liquid.

5. The substrate processing apparatus according to claim 1, further comprising:
a mixing unit that is provided on the supply line closer to the supply unit than the connecting portion, and further generates mixed solution of the processing liquid flowing through the supply line and second processing liquid, wherein
the supply unit supplies, to the substrate, the mixed solution that is generated by the mixing unit.

6. The substrate processing apparatus according to claim 5, wherein
the processing liquid includes a sulfuric acid, and
the second processing liquid includes a hydrogen peroxide.

7. A substrate processing method executed by a substrate processing apparatus including: a retaining tank that retains therein processing liquid; a circulation line that returns, to the retaining tank, the processing liquid delivered from the retaining tank; a supply line that connects the circulation line to a supply unit that supplies the processing liquid to a substrate; a returning line that is connected to the supply line to return the processing liquid from the supply line to the retaining tank; and a flowmeter and a constant-pressure valve that are provided on the supply line on an upper flow side than a connecting portion of the returning line and the supply line, the method comprising:
during a waiting time interval in which the processing liquid is caused to flow into the returning line not to supply the processing liquid from the supply unit to the substrate, calculating an opening degree of the constant-pressure valve in supplying the processing liquid to the substrate based on a measurement value of the flowmeter and an opening degree of the constant-pressure valve; and
during a supplying time interval in which the processing liquid is caused to flow into the supply unit to supply the processing liquid to the substrate, setting an initial opening degree of the constant-pressure valve to the calculated opening degree.
